(19) United States
(12) Patent Application Publication
(10) Pub. No.: US 2024/0162283 A1
(43) Pub. Date: May 16, 2024

(54) Semiconductor Structure and Method for Manufacturing the Same

(71) Applicant: Enkris Semiconductor (Wuxi), Ltd., Wuxi (CN)

(72) Inventors: Weihua LIU, Wuxi (CN); Kai CHENG, Wuxi (CN)

(73) Assignee: Enkris Semiconductor (Wuxi), Ltd., Wuxi (CN)

(21) Appl. No.: 18/350,612

(22) Filed: Jul. 11, 2023

(30) Foreign Application Priority Data
Nov. 11, 2022 (CN) 202211415326.1

(51) Int. Cl. H01L 29/06; H01L 21/02; H01L 21/225; H01L 21/266

(52) U.S. Cl. CPC H01L 29/0607; H01L 21/02178; H01L 21/0254; H01L 21/2258; H01L 21/266

(57) ABSTRACT

A semiconductor structure includes a substrate, a first semiconductor layer, a second semiconductor layer and a p-type ion doping layer sequentially disposed, the p-type ion doping layer includes an activation region and a passivation region enclosing the activation region, and the activation region is an oxygen-doped region. Hydrogen doped in the p-type ion doping layer can be replaced by low-temperature annealing after a process of implementing oxygen ion-implantation, so as to improve activation efficiency of the p-type ion doping layer; the activation region in a gate electrode region and the passivation region in an non-gate electrode region are formed by using a method for selectively activating the p-type ion doping layer, avoiding etching of the p-type ion doping layer, and thus avoiding etching losses; and a plurality of patterned activation regions are obtained by selectively activating on a same substrate, which facilitates batch preparation of enhancement mode semiconductor devices.

### CROSS-REFERENCE TO RELATED APPLICATIONS

The present application claims the priority of Chinese Patent Application No. 202211415326.1, filed on Nov. 11, 2022, the entire content of which is incorporated herein by reference.

### TECHNICAL FIELD

The present application relates to the field of semiconductor technologies, and in particular, to a semiconductor structure and a method for manufacturing the same.

### BACKGROUND

As a typical representative of third generation of semiconductor materials, wide band semiconductor materials, such as group III nitrides, have excellent characteristics such as a wide band gap, high voltage resistance, high temperature resistance, high electron saturation speed and high electron drift speed, and easy to form a high-quality heterojunction structure, which are very suitable for manufacturing high-temperature, high-frequency and high-power electronic devices.

Enhancement mode devices have a wide range of applications in the field of power electronics due to their normally-off characteristics. There are many ways to manufacture the enhancement mode devices, such as depletion of a two-dimensional electron gas by setting a p-type semiconductor at a gate electrode. Dopants in a p-type semiconductor material are usually activated by thermal annealing, and however, current annealing methods have problems with low activation efficiency and damage to semiconductor materials. In addition, there are demands for a p-type semiconductor to be etched during a device manufacturing process, but it is difficult to control an etching accuracy during an etching process, and therefore, etching damages are introduced.

### SUMMARY

In view of this, embodiments of the present application provide a semiconductor structure and a method for manufacturing the same, in which a p-type ion doping layer is selectively doped with an oxygen element, to solve problems of difficult activation and etching damages of a p-type semiconductor.

According to a first aspect, embodiments of the present application provide a semiconductor structure, including: a substrate; a first semiconductor layer and a second semiconductor layer sequentially disposed on the substrate; and a p-type ion doping layer disposed on the second semiconductor layer. The p-type ion doping layer includes an activation region and a passivation region enclosing the activation region, and the activation region is an oxygen-doped region.

In an optional embodiment, an upper surface, a lower surface and sidewalls of the activation region are enclosed by the passivation region; or an upper surface and sidewalls of the activation region are enclosed by the passivation region.

In an optional embodiment, a p-type ion doped in the p-type ion doping layer includes a magnesium ion.

In an optional embodiment, the number of magnesium hydrogen bonds in the activation region is less than that in the passivation region.

In an optional embodiment, along a direction away from the substrate, a variation trend of a content of an oxygen element doped in a material of the activation region includes one of the following: uniformly decreasing, decreasing in a hopping manner, decreasing in a step-like manner, or first increasing and then decreasing.

In an optional embodiment, a content of an oxygen element doped in a material of the activation region is less than 1E21 atoms/cm³.

In an optional embodiment, a ratio of a content of an oxygen element doped in a material of the activation region to a content of a p-type ion doped in the material of the activation region is greater than 0.1 and less than 10.

In an optional embodiment, a material of the p-type ion doping layer is one of or a combination of GaN, InGaN, AlGaN, or InAlGaN.

In an optional embodiment, the semiconductor structure further includes: a protective layer disposed on the p-type ion doping layer, and a material of the protective layer is AlN or AlGaN.

In an optional embodiment, the semiconductor structure further includes: a source electrode disposed on the second semiconductor layer and in ohmic contact with the second semiconductor layer; a drain electrode disposed on the second semiconductor layer and in ohmic contact with the second semiconductor layer; and a gate electrode disposed on the p-type ion doping layer and in Schottky contact with the p-type ion doping layer.

In an optional embodiment, the p-type ion doping layer includes a plurality of activation regions, and the plurality of activation regions are arranged at intervals in a plane parallel to the substrate.

According to another aspect, embodiments of the present application provide a method for manufacturing a semiconductor structure, including: S1. providing a substrate and forming a first semiconductor layer and a second semiconductor layer on the substrate; S2. forming a p-type ion doping layer on the second semiconductor layer; S3. manufacturing a mask layer patterned on an upper surface of the p-type ion doping layer, a window being formed in the mask layer; and S4. implanting, by using ion-implantation, an oxygen-containing gas into the p-type ion doping layer below the window, to form an activation region of which material is doped with an oxygen ion and a passivation region of which material is not doped with the oxygen ion.

In an optional embodiment, an upper surface, a lower surface and side walls of the activation region are enclosed by the passivation region; or an upper surface and side walls of the activation region are enclosed by the passivation region.

In an optional embodiment, a p-type ion doped in the p-type ion doping layer includes a magnesium ion.

In an optional embodiment, the number of magnesium hydrogen bonds in the activation region is less than that in the passivation region.

In an optional embodiment, depth of the activation region is controlled by controlling energy of the ion-implantation.

In an optional embodiment, along a direction away from the substrate, a variation trend of a content of an oxygen element doped in a material of the activation region is controlled by controlling energy of the ion-implantation, and the variation trend includes one of the following: uniformly decreasing, decreasing in a hopping manner, decreasing in a step-like manner, or first increasing and then decreasing.

In an optional embodiment, a method of the ion-implantation includes multiple implantations.

In an optional embodiment, the method for manufacturing the semiconductor structure further includes: etching the p-type ion doping layer to expose the second semiconductor layer, to form a source electrode region and a drain electrode region; disposing, in the source electrode region, a source electrode that is in ohmic contact with the second semiconductor layer; disposing, in the drain electrode region, a drain electrode that is in ohmic contact with the second semiconductor layer; and disposing, on the p-type ion doping layer, a gate electrode that is in Schottky contact with the p-type ion doping layer.

In an optional embodiment, a plurality of p-type ion doping layers, which are patterned and to be activated, are exposed by the mask layer, a plurality of patterned activation regions are formed after an oxygen ion is implanted, and the plurality of activation regions are arranged at intervals in a plane parallel to the substrate.

### BRIEF DESCRIPTION OF THE DRAWINGS

FIG. 1 is a schematic structural diagram of a semiconductor structure according to an embodiment of the present application.

FIG. 2 is a schematic structural diagram of a semiconductor structure according to an embodiment of the present application.

FIG. 3a to FIG. 3d are schematic variation diagrams of a doping concentration of an oxygen element doped in a material of an activation region according to an embodiment of the present application.

FIG. 4 is a top view structural diagram of a semiconductor structure according to an embodiment of the present application.

FIG. 5 is a flowchart of a method for manufacturing a semiconductor structure according to an embodiment of the present application.

FIG. 6 to FIG. 9 are schematic decomposition diagrams of a semiconductor structure during a manufacturing process according to an embodiment of the present application.

FIG. 10 is a schematic structural diagram of a semiconductor structure according to an embodiment of the present application.

FIG. 11 is a top view structural diagram of a semiconductor structure according to an embodiment of the present application.

### DETAILED DESCRIPTION OF THE EMBODIMENTS

The following clearly and completely describes the technical solutions in the embodiments of the present application with reference to the accompanying drawings in the embodiments of the present application. Apparently, the described embodiments are a part rather than all of the embodiments of the present application. All other embodiments obtained by a person of ordinary skill in the art based on the embodiments of the present application without creative efforts shall fall within the protection scope of the present application.

In the related technologies, AlGaN/GaN heterojunction are widely used in semiconductor structures such as High Electron Mobility Transistors (HEMT) due to a high concentration of two-dimensional electron gases (2DEG) at an AlGaN/GaN interface caused by strong spontaneous and piezoelectric polarization of the AlGaN/GaN heterojunction.

There are many ways to manufacture enhancement mode devices, such as depletion of a two-dimensional electron gas by setting a p-type semiconductor at a gate electrode. A magnesium (Mg) ion is a suitable dopant for p-type semiconductor materials. Typical annealing temperatures for the conventional thermal annealing are in a range from 600° C. to 900° C. to activate the Mg ion, but the conventional annealing methods have problems of low activation efficiency and damage to semiconductor materials, and therefore, finding a simple and low-temperature method to activate the Mg ion has become an urgent problem to be solved. In addition, during a device manufacturing process, there is a need to etch the p-type semiconductor between a gate electrode and a source electrode, as well as the p-type semiconductor between a gate electrode and a drain electrode, but it is difficult to control an etching accuracy, and therefore, etching damages are introduced, ultimately leading to a decrease in output current density, an increase in leakage current of the gate electrode and a decrease in device stability.

In order to solve the problems of difficult activation and etching damage of the p-type semiconductor in the related technologies, the present application provides a semiconductor structure and a method for manufacturing the same. The semiconductor structure includes a substrate, a first semiconductor layer, a second semiconductor layer and a p-type ion doping layer which are sequentially disposed, the p-type ion doping layer includes an activation region and a passivation region enclosing the activation region, and the activation region is an oxygen-doped region. In the present application, hydrogen doped in the p-type ion doping layer can be replaced by low-temperature annealing after a process of implementing oxygen ion-implantation, so as to improve activation efficiency of the p-type ion doping layer; the activation region in a gate electrode region and the passivation region in an non-gate electrode region are formed by using a method for selectively activating the p-type ion doping layer, avoiding etching of the p-type ion doping layer, and thus avoiding etching losses; and a plurality of patterned activation regions are obtained by selectively activating on a same substrate, which facilitates batch preparation of the enhancement mode semiconductor devices.

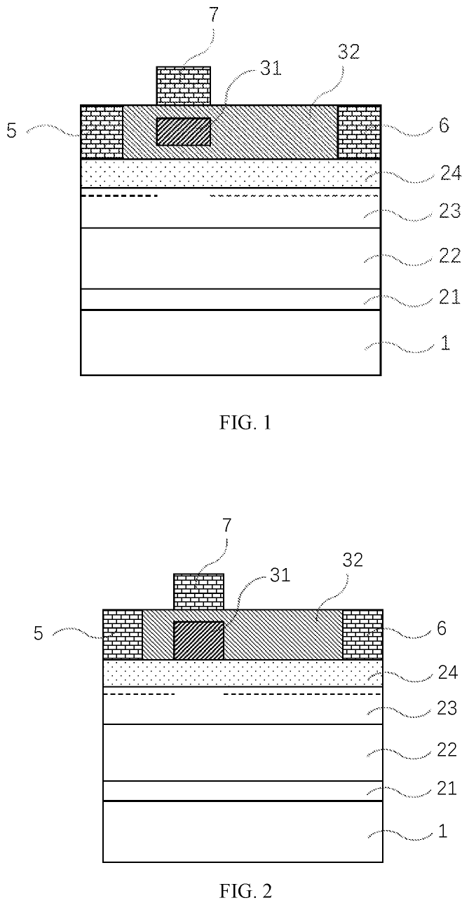

A semiconductor structure and a method for manufacturing the same provided by the present application may be further exemplified below in combination with FIG. 1 to FIG. 11.

FIG. 1 is a schematic structural diagram of a semiconductor structure according to an embodiment of the present application. As shown in FIG. 1, the semiconductor structure includes: a substrate 1; a first semiconductor layer 23 and a second semiconductor layer 24 sequentially disposed on the substrate 1; and a p-type ion doping layer disposed on the second semiconductor layer 24. The p-type ion doping layer includes an activation region 31 and a passivation region 32 enclosing the activation region 31, and the activation region 31 is an oxygen-doped region.

In some embodiments, the semiconductor structure further includes a source electrode 5, a drain electrode 6 and a gate electrode 7. As shown in FIG. 1, the source electrode 5 is dispose on the second semiconductor layer 24 and in ohmic contact with the second semiconductor layer 24, the drain electrode 6 is dispose on the second semiconductor layer 24 and in ohmic contact with the second semiconductor layer 24, and the gate electrode 7 is dispose on the p-type ion doping layer and in Schottky contact with the p-type ion doping layer. The source electrode 5, the drain electrode 6 and the gate electrode 7 may be made of metal materials such as a nickel alloy, also may be made of metallic oxides or semiconductor materials, and the specific fabrication materials of the source electrode 5, the drain electrode 6 and the gate electrode 7 are not limited in the embodiments of the present application.

Based on the device structure shown in FIG. 1, after etching off the p-type ion doping layer above a source electrode region and a drain electrode region, to expose the source electrode region and the drain electrode region on a surface of the second semiconductor layer 24, the source electrode 5 and the drain electrode 6 are manufactured to form the final device structure shown in FIG. 1, and all surfaces, except surfaces above the source electrode region and the drain electrode region, of the second semiconductor layer 24 are covered by a final prepared shape of the p-type ion doping layer.

In some embodiments, FIG. 2 is a schematic structural diagram of a semiconductor structure according to an embodiment of the present application. An upper surface, a lower surface and side walls of the activation region 31 are enclosed by the passivation region 32 (shown in FIG. 1), or an upper surface and side walls of the activation region 31 are enclosed by the passivation region 32 (shown in FIG. 2). There is no need to perform etching operations on the p-type ion doping layer, the activation region in the gate electrode region and the passivation region in the non-gate electrode region are formed by selectively activating the p-type ion doping layer, avoiding the etching losses. The passivation region 32 between the source electrode 5 and the gate electrode 7 and the passivation region 32 between the drain electrode 6 and the gate electrode 7 may also play an electrical insulation role, enhancing ohmic contact of the source electrode 5 and the drain electrode 6, and increasing breakdown voltage. The passivation region 32 is disposed below the gate electrode 7, which can also reduce the leakage current of the gate electrode 7.

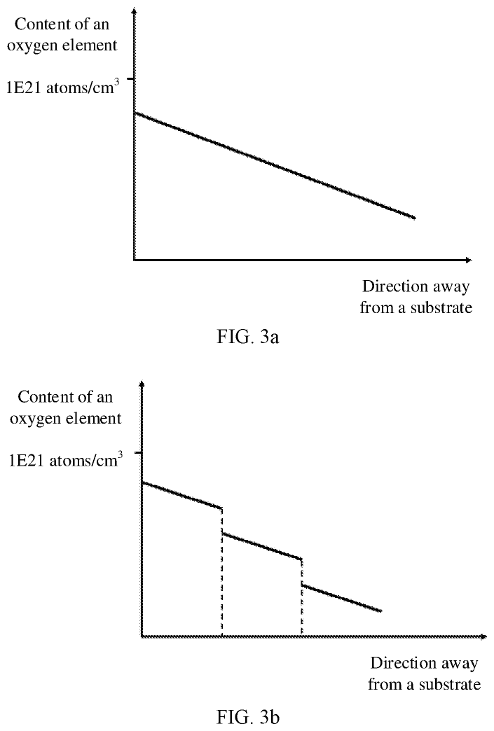

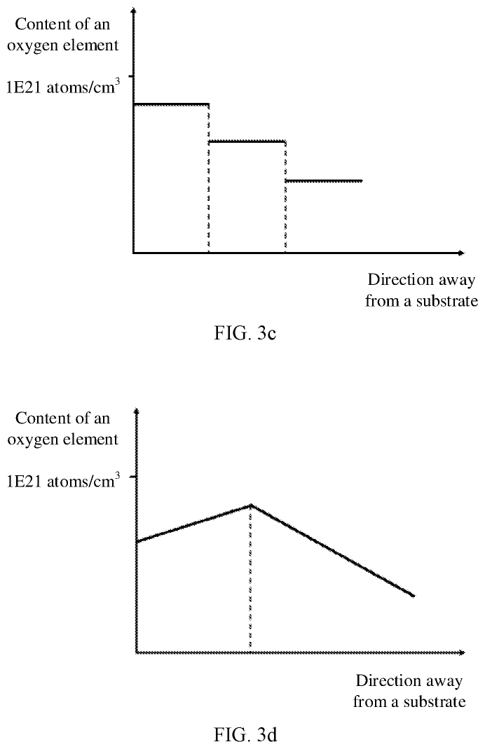

In some embodiments, a content of an oxygen element doped in a material of the activation region 31 is less than 1E21 atoms/cm³, and a ratio of the content of the oxygen element doped in the material of the activation region 31 to a content of a p-type ion doped in the material of the activation region 31 is greater than 0.1 and less than 10. The activation efficiency of the p-type ion doped in the material of the activation region 31 is controlled by controlling the content of the oxygen element doped in the material of the activation region 31. FIG. 3a to FIG. 3d are schematic variation diagrams of a doping concentration of an oxygen element doped in a material of an activation region according to an embodiment of the present application. Along a direction away from the substrate, a variation trend of the content of the oxygen element doped in the material of the activation region 31 includes one of the following: uniformly decreasing (shown in FIG. 3a), decreasing in a hopping manner (shown in FIG. 3b), decreasing in a step-like manner (shown in FIG. 3c), or first increasing and then decreasing (shown in FIG. 3d). A concentration gradient of electron holes in the activation region is controlled by controlling the content of the oxygen element doped in the material of the activation region 31, which helps to reduce the leakage current of the gate electrode 7 of the semiconductor structure and enhance the breakdown voltage. The closer the activation region 31 to the substrate, the higher the content of the oxygen element doped in the material of the activation region 31, i.e., the p-type doped ions have higher activation efficiency, which has a better depletion effect on the two-dimensional electron gas below the activation region 31, while the farther away from the substrate, the lower the content of the oxygen element doped in the material of the activation region 31, i.e., the p-type doped ions have lower activation efficiency, which can reduce the leakage current of the gate electrode 7.

In some embodiments, a material of the substrate 1 may be sapphire, silicon carbide, silicon, GaN or diamond. Materials of the first semiconductor layer 23 and the second semiconductor layer 24 may include a group III nitride material, and the two-dimensional electron gas may be formed at an interface between the first semiconductor layer 23 and the second semiconductor layer 24. In one alternative solution, the first semiconductor layer 23 is a GaN layer and the second semiconductor layer 24 is an AlGaN layer. In other alternative solutions, material combination of the first semiconductor layer 23 and the second semiconductor layer 24 may also be GaN/AlN, GaN/InN, GaN/InAlGaN, GaAs/AlGaAs, GaN/InAlN or InN/InAlN.

In some embodiments, a material of the p-type ion doping layer may be one of or a combination of GaN, InGaN, AlGaN, or InAlGaN. A p-type ion doped in the p-type ion doping layer may be a Mg ion, to deplete the two-dimensional electron gas below the gate electrode region, forming the enhancement mode device. An oxygen hydrogen bond may be formed by combining the oxygen element and the hydrogen doped in the p-type ion doping layer, thereby breaking a magnesium hydrogen bond to release the magnesium ion, and thus achieving p-type activation of the p-type ion doping layer to form the activation region 31. As a result, the number of magnesium hydrogen bonds in the activation region 31 is less than that in the passivation region 32, the magnesium ion doped in the material of the activation region 31 are released and activated to form electron holes, while the magnesium ion doped in a material of the passivation region 32 are not released and activated, and therefore, the electron holes cannot be formed.

In some embodiments, between the first semiconductor layer 23 and the substrate 1, there may be a nucleation layer 21 and a buffer layer 22. A material of the nucleation layer 21 may be AlN, AlGaN or the like. A material of the buffer layer 22 may include at least one of AlN, GaN, AlGaN or AlInGaN. Setting the nucleation layer 21 may alleviate lattice mismatch and thermal mismatch between an epitaxially grown semiconductor layer (e.g., the first semiconductor layer 23) and the substrate 1, and setting the buffer layer 22 may decrease dislocation density and defect density of the epitaxially grown semiconductor layer, to improve crystal quality.

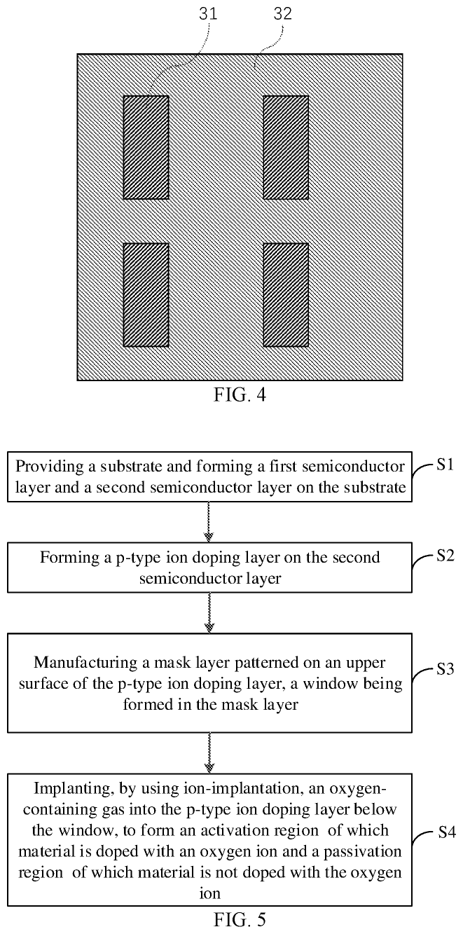

In some embodiments, FIG. 4 is a top view structural diagram of a semiconductor structure according to an embodiment of the present application. As shown in FIG. 4, a plurality of activation regions 31 are patterned on a same substrate, and the activation region 31 is enclosed by the passivation region 32. The plurality of activation regions, which are disposed in the gate electrode region and are p-type, are obtained by selectively activating on a same substrate once, and the plurality of activation regions are arranged at intervals in a plane parallel to the substrate, making the process simple and efficient, which facilitates the batch preparation of the enhancement mode semiconductor devices.

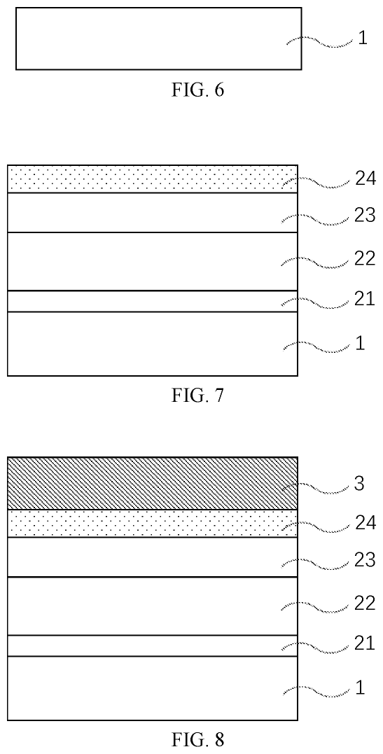

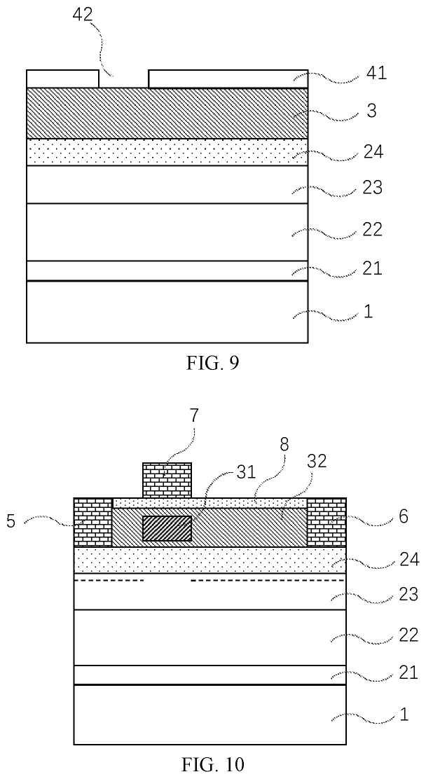

According to another aspect of the present application, FIG. 5 is a flowchart of a method for manufacturing a semiconductor structure according to an embodiment of the present application. FIG. 6 to FIG. 9 are schematic decomposition diagrams of a semiconductor structure during a manufacturing process according to an embodiment of the present application. As shown in FIG. 5, the method for manufacturing the semiconductor structure provided by the embodiments of the present application includes the following steps.
S1: as shown in FIG. 6 and FIG. 7, providing a substrate 1 and forming a first semiconductor layer 23 and a second semiconductor layer 24 on the substrate 1. A material of the substrate 1 may be one of sapphire, silicon carbide, silicon, GaN or diamond. In some embodiments, a nucleation layer 21 and a buffer layer 22 may be grown sequentially on the substrate 1 before the first semiconductor layer 23 is grown. The nucleation layer 21, the buffer layer 22, the first semiconductor layer 23 and the second semiconductor layer 24 have been described previously and may not be repeated here.
S2: as shown in FIG. 8, forming the p-type ion doping layer 3 on the second semiconductor layer 24. A method for forming the p-type ion doping layer 3 includes: Atomic Layer Deposition (ALD), or Chemical Vapor Deposition (CVD), or Molecular Beam Epitaxy (MBE), or Plasma Enhanced Chemical Vapor Deposition (PECVD), or Low Pressure Chemical Vapor Deposition (LPCVD), or Metal-Organic Chemical Vapor Deposition (MOCVD), or a combination thereof. It should be appreciated that the method for forming the p-type ion doping layer 3 described herein is only an example, and the p-type ion doping layer 3 in the present application may be formed by any method known to those skilled in the art.
S3: as shown in FIG. 9, manufacturing a mask layer 41 patterned on an upper surface of the p-type ion doping layer 3, a window 42 being formed in the mask layer 41.
S4: implanting, by using ion-implantation, an oxygen-containing gas into the p-type ion doping layer 3 below the window 42, to form a plurality of patterned activation regions 31 of which material are doped with an oxygen ion, and a passivation region 32 of which material is not doped with the oxygen ion (shown in FIG. 2). The activation region 31 in a gate electrode region and the passivation region 32 in an non-gate electrode region are formed by selectively activating the p-type ion doping layer, avoiding etching of the p-type ion doping layer, and thus avoiding etching losses and simplifying a device manufacturing process.

It should be noted that in step S4, after the oxygen-containing gas is implanted into the p-type ion doping layer 3 below the window 42 by using the ion-implantation, an annealing operation may be performed, and thus completing activation of the activation region 31. In the related technologies, annealing under high temperature conditions is required for GaN layers doped with a Mg element, to cut off a bonding junction of a Mg—H complex, achieving p-type activation. However, when the annealing under the high temperature conditions is performed on the GaN layers, it is easy to drop a N element from the GaN layers, so that donor type defects may be generated in the GaN layers due to the dropping of the N element, damaging device performance of the semiconductor structure. Since an oxygen hydrogen bond has stronger ionic bonding energy than a magnesium hydrogen bond, after the material is doped with the oxygen ion, the bonding junction of the Mg—H complex may be cut off by annealing under low temperature conditions, to further complete p-type activation of the GaN layers doped with the Mg element. A method of the ion-implantation includes multiple implantations, and activation efficiency of the activation region 31 may be improved by using the multiple implantations.

In some embodiments, FIG. 10 is a schematic structural diagram of a semiconductor structure according to an embodiment of the present application. A protective layer 8 is manufactured on the p-type ion doping layer, and a material of the protective layer 8 is AlN or AlGaN. Setting the protective layer 8 can prevent damage to the activation region 31 during an annealing process, so as to improve quality of a surface morphology of the activation region 31, thereby improving problems of leakage voltage and pre-breakdown of devices and improving reliability of the devices. The protective layer 8 is retained in the devices, which can also reduce leakage of a gate electrode and increase device swing.

In some embodiments, the method for manufacturing the semiconductor structure further includes: etching the p-type ion doping layer to expose the second semiconductor layer 24, to form a source electrode region and a drain electrode region; disposing, in the source electrode region, a source electrode 5 that is in ohmic contact with the second semiconductor layer 24; disposing, in the drain electrode region, a drain electrode 6 that is in ohmic contact with the second semiconductor layer 24; and disposing, on the p-type ion doping layer, a gate electrode 7 that is in Schottky contact with the p-type ion doping layer. The source electrode 5, the drain electrode 6 and the gate electrode 7 may be made of metal materials such as a nickel alloy, also may be made of metallic oxides or semiconductor materials, and the specific fabrication materials of the source electrode 5, the drain electrode 6 and the gate electrode 7 are not limited in the embodiments of the present application.

In some embodiments, depth and thickness of the activation region 31 are controlled by controlling energy of the ion-implantation, to form the device structure shown in FIG. 1 and FIG. 2. Depth of the activation region 31 located in the gate electrode region is controlled by controlling energy of oxygen ion-implantation. A passivation layer is between the activation region 31 and the gate electrode 7, which facilitates to reduce leakage current of the gate electrode of the semiconductor structure and increase breakdown voltage compared with the existing scheme of direct contact between the activation region and the gate electrode. An upper surface, a lower surface and side walls of the activation region 31 are enclosed by the passivation region 32 (shown in FIG. 1), or an upper surface and side walls of the activation region 31 are enclosed by the passivation region 31 (shown in FIG. 2). There is no need to perform etching operations on the p-type ion doping layer, the activation region in the gate electrode region and the passivation region in the non-gate electrode region are formed by selectively activating the p-type ion doping layer, avoiding the etching losses. The passivation region 32 between the source electrode 5 and the gate electrode 7 and the passivation region 32 between the drain electrode 6 and the gate electrode 7 may also play an electrical insulation role, enhancing ohmic contact of the source electrode and the drain electrode, and increasing the breakdown voltage. The passivation region 32 is disposed below the gate electrode, which can also reduce the leakage current of the gate electrode.

In some embodiments, along a direction away from the substrate, a variation trend of a content of an oxygen element doped in the material of the activation region 31 is controlled by uniformly reducing the energy of the oxygen ion-implantation or decreasing the energy of the oxygen ion-implantation in a hopping manner, and thus the variation trend includes one of the following: uniformly decreasing (shown in FIG. 3a), decreasing in a hopping manner (shown in FIG. 3b), decreasing in a step-like manner (shown in FIG. 3c), or first increasing and then decreasing (shown in FIG. 3d). A concentration gradient of electron holes in the activation region is controlled by controlling the content of the oxygen element doped in the material of the activation region 31, which facilitates to reduce the leakage current of the gate electrode of the semiconductor structure and enhance the breakdown voltage. The closer the activation region 31 to the substrate, the higher the content of the oxygen element doped in the material of the activation region 31, i.e., p-type doped ions have higher activation efficiency, which has a better depletion effect on the two-dimensional electron gas below the activation region 31, while the further away from the substrate, the lower the content of the oxygen element doped in the material of the activation region 31, i.e., the p-type doped ions have lower activation efficiency, which can reduce the leakage current of the gate electrode 7.

In some embodiments, a p-type ion doped in the p-type ion doping layer may be a Mg ion, to deplete a two-dimensional electron gas below the gate electrode region, forming an enhancement mode device. After the oxygen ion is implanted into the p-type ion doping layer, an oxygen hydrogen bond may be formed by combining the oxygen element and the hydrogen doped in the p-type ion doping layer, thereby breaking a magnesium hydrogen bond to release the magnesium ion, and thus achieving p-type activation of the p-type ion doping layer to form the activation region 31. As a result, the activation region 31 contains the oxygen hydrogen bond, and the number of magnesium hydrogen bonds in the activation region 31 is less than that in the passivation region 32, the magnesium ion doped in the material of the activation region 31 are released and activated to form electron holes, while the magnesium ion doped in a material of the passivation region 32 are not released and activated, and therefore, the electron holes cannot be formed.

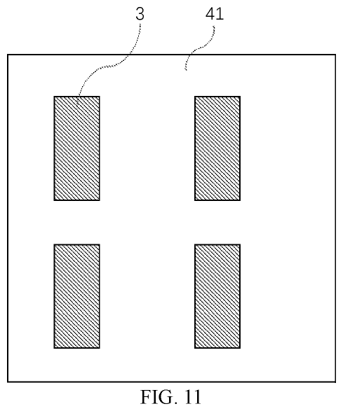

In some embodiments, FIG. 11 is a top view structural diagram of a semiconductor structure according to an embodiment of the present application. A plurality of p-type ion doping layers, which are patterned and to be activated on a same substrate, are exposed by the patterned mask layer 41. A plurality of activation regions 31, which are disposed in the gate electrode region and are p-type, can be obtained by selectively activating on a same substrate once, and the plurality of activation regions 31 are arranged at intervals in a plane parallel to the substrate 1, making the process simple and efficient, which facilitates batch preparation of enhancement mode semiconductor devices.

The present application provides a semiconductor structure and a method for manufacturing the same, and the semiconductor structure includes a substrate, a first semiconductor layer, a second semiconductor layer and a p-type ion doping layer which are sequentially disposed, the p-type ion doping layer includes an activation region and a passivation region enclosing the activation region, and the activation region is an oxygen-doped region.

In the present application, a beneficial effect 1 is as follows. The hydrogen doped in the p-type ion doping layer can be replaced by the low-temperature annealing after the process of implementing the oxygen ion-implantation, so as to improve the activation efficiency of the p-type ion doping layer; the activation region in the gate electrode region and the passivation region in the non-gate electrode region are formed by using the method for selectively activating the p-type ion doping layer, avoiding etching of the p-type ion doping layer, and thus avoiding the etching losses; and the passivation region between the source electrode and the gate electrode and the passivation region between the drain electrode and the gate electrode may also play an electrical insulation role.

In the present application, a beneficial effect 2 is as follows. The depth of the activation region located in the gate electrode region is controlled by controlling the energy of the oxygen ion-implantation; the passivation layer is between the activation region and the gate electrode, which facilitates to reduce the leakage current of the gate electrode of the semiconductor structure and increase the breakdown voltage compared with the existing scheme of direct contact between the activation region and the gate electrode; and the activation region of this application is flexible.

In the present application, a beneficial effect 3 is as follows. Along the direction away from the substrate, the variation trend of the content of the oxygen element doped in the material of the activation region of the present application includes one of the following: uniformly decreasing, decreasing in a hopping manner, decreasing in a step-like manner, or first increasing and then decreasing. The concentration gradient of the electron holes in the activation region is controlled by controlling the content of the oxygen element doped in the material of the activation region, which facilitates to reduce the leakage current of the gate electrode of the semiconductor structure and enhance the breakdown voltage.

In the present application, a beneficial effect 4 is as follows. The p-type ion doping layer of the present application includes the plurality of activation regions, and the plurality of activation regions are arranged at intervals in the plane parallel to the substrate, making the process simple and efficient, which facilitates the batch preparation of the enhancement mode semiconductor devices.

It is to be appreciated that the term “including”, and variations thereof used in the present application are open-ended, i.e., “including but not limited to”. The term “an embodiment” means “at least one embodiment”; and the term “another embodiment” means “at least one additional embodiment”. In the specification, the schematic expressions of the above terms do not have to refer to the same embodiments or examples. Furthermore, the specific features, structures, materials or characteristics described may be combined in a suitable manner in any one or more embodiments or examples. In addition, without contradicting each other, a person skilled in the art may combine and constitute different embodiments or examples described in this specification, and the features in different embodiments or examples.

The foregoing descriptions are merely preferred embodiments of the present application, but are not intended to limit the protection scope of the present application. Any modifications, equivalent replacements, etc. made within the spirit and principles of the present application should be included in the protection scope of the present application.

What is claimed is:

1. A semiconductor structure, comprising:
a substrate;
a first semiconductor layer and a second semiconductor layer sequentially disposed on the substrate; and
a p-type ion doping layer disposed on the second semiconductor layer, wherein the p-type ion doping layer comprises an activation region and a passivation region enclosing the activation region, and the activation region is an oxygen-doped region.

2. The semiconductor structure according to claim 1, wherein an upper surface, a lower surface and sidewalls of the activation region are enclosed by the passivation region; or
an upper surface and sidewalls of the activation region are enclosed by the passivation region.

3. The semiconductor structure according to claim 1, wherein a p-type ion doped in the p-type ion doping layer comprises a magnesium ion.

4. The semiconductor structure according to claim 3, wherein the number of magnesium hydrogen bonds in the activation region is less than that in the passivation region.

5. The semiconductor structure according to claim 1, wherein along a direction away from the substrate, a variation trend of a content of an oxygen element doped in a material of the activation region comprises one of the following: uniformly decreasing, decreasing in a hopping manner, decreasing in a step-like manner, or first increasing and then decreasing.

6. The semiconductor structure according to claim 1, wherein a content of an oxygen element doped in a material of the activation region is less than 1E21 atoms/cm³.

7. The semiconductor structure according to claim 1, wherein a ratio of a content of an oxygen element doped in a material of the activation region to a content of a p-type ion doped in the material of the activation region is greater than 0.1 and less than 10.

8. The semiconductor structure according to claim 1, wherein a material of the p-type ion doping layer is one of or a combination of GaN, InGaN, AlGaN, or InAlGaN.

9. The semiconductor structure according to claim 1, further comprising:
a protective layer disposed on the p-type ion doping layer, wherein a material of the protective layer is AlN or AlGaN.

10. The semiconductor structure according to claim 1, further comprising:
a source electrode disposed on the second semiconductor layer and in ohmic contact with the second semiconductor layer;
a drain electrode disposed on the second semiconductor layer and in ohmic contact with the second semiconductor layer; and
a gate electrode disposed on the p-type ion doping layer and in Schottky contact with the p-type ion doping layer.

11. The semiconductor structure according to claim 1, wherein the p-type ion doping layer comprises a plurality of activation regions, and the plurality of activation regions are arranged at intervals in a plane parallel to the substrate.

12. A method for manufacturing a semiconductor structure, comprising:
S1: providing a substrate and forming a first semiconductor layer and a second semiconductor layer on the substrate;
S2: forming a p-type ion doping layer on the second semiconductor layer;
S3: manufacturing a mask layer patterned on an upper surface of the p-type ion doping layer, a window being formed in the mask layer; and
S4: implanting, by using ion-implantation, an oxygen-containing gas into the p-type ion doping layer below the window, to form an activation region of which material is doped with an oxygen ion and a passivation region of which material is not doped with the oxygen ion.

13. The method for manufacturing the semiconductor structure according to claim 12, wherein an upper surface, a lower surface and side walls of the activation region are enclosed by the passivation region; or
an upper surface and side walls of the activation region are enclosed by the passivation region.

14. The manufacturing method for a semiconductor structure according to claim 12, wherein a p-type ion doped in the p-type ion doping layer comprises a magnesium ion.

15. The method for manufacturing the semiconductor structure according to claim 12, wherein the number of magnesium hydrogen bonds in the activation region is less than that in the passivation region.

16. The method for manufacturing the semiconductor structure according to claim 12, wherein a depth of the activation region is controlled by controlling energy of the ion-implantation.

17. The method for manufacturing the semiconductor structure according to claim 12, wherein along a direction away from the substrate, a variation trend of a content of an oxygen element doped in a material of the activation region is controlled by controlling energy of the ion-implantation, and the variation trend comprises one of the following: uniformly decreasing, decreasing in a hopping manner, decreasing in a step-like manner, or first increasing and then decreasing.

18. The method for manufacturing the semiconductor structure according to claim 12, wherein a method of the ion-implantation comprises multiple implantations.

19. The method for manufacturing the semiconductor structure according to claim 12, further comprising:
etching the p-type ion doping layer to expose the second semiconductor layer, to form a source electrode region and a drain electrode region;
disposing, in the source electrode region, a source electrode that is in ohmic contact with the second semiconductor layer;
disposing, in the drain electrode region, a drain electrode that is in ohmic contact with the second semiconductor layer; and
disposing, on the p-type ion doping layer, a gate electrode that is in Schottky contact with the p-type ion doping layer.

20. The method for manufacturing the semiconductor structure according to claim 12, wherein a plurality of p-type ion doping layers, which are patterned and to be activated, are exposed by the mask layer, a plurality of patterned activation regions are formed after an oxygen ion is implanted, and the plurality of activation regions are arranged at intervals in a plane parallel to the substrate.
